(19) United States
(12) Patent Application Publication
(10) Pub. No.: US 2006/0197232 A1
(43) Pub. Date: Sep. 7, 2006

(54) Planar microspring integrated circuit chip interconnection to next level

(75) Inventors: Andrew Ah Ong Tay, Singapore (SG); Simon Saw-Teong Ang, Fayetteville, AR (US); Ebin Liao, Singapore (SG)

Correspondence Address: MICHAEL W. TAYLOR, P.O. BOX 3791, ORLANDO, FL, 32802-3791, US

(73) Assignees: National University of Singapore, Singapore (SG); Agency for Science, Technology and Research, Centros (SG); Georgia Tech Research Corporation, Atlanta, GA (US)

(21) Appl. No.: 11/361,613

(22) Filed: Feb. 24, 2006

Related U.S. Application Data
(60) Provisional application No. 60/655,903, filed on Feb. 25, 2005.

(51) Int. Cl. H01L 23/48; H01L 21/44

(52) U.S. Cl. 257/779; 438/612; 257/E23.023

(57) ABSTRACT

An interconnect structure for interconnecting an integrated circuit (IC) chip to a next level, a method of fabricating the interconnect at wafer level, and a method of interconnecting an integrated circuit (IC) chip to the next level. The interconnect structure comprises one or more planar micro-spring elements formed on a packaging surface of the chip and connected to an interconnection pad; wherein the interconnection pad is resiliently moveable horizontally and vertically with respect to the surface of the chip. A layer of solder is preferably electroplated onto the interconnection pad to provide interconnection to the next level. In a variation of the interconnect structure, a metal column is fabricated onto the interconnection pad prior to electroplating the solder layer.

### RELATED APPLICATION

This application claims the benefit of U.S. Provisional Application Ser. No. 60/655,903 filed Feb. 25, 2005, the entire contents of which are incorporated herein by reference.

### FIELD OF THE INVENTION

The present invention relates broadly to an interconnect structure for interconnecting an integrated circuit (IC) chip to a next level, to a method of interconnecting an integrated circuit (IC) chip to a next. level and to a method of fabricating the interconnect structure on an integrated circuit (IC) chip at wafer level.

### BACKGROUND OF THE INVENTION

It is expected that flip-chip technology will ultimately replace the current wire bonding techniques as the main-stream chip-to-next-level interconnection technology because of the superior electrical performance and compact form factors intrinsic to the flip chip technology. Solder joint bonding has been a widely-used interconnection option between the flipped chip and next level package. Up to now, this technology has worked well, despite the thermal mismatch between the silicon die and the packaging substrate, as the technology has been typically applied to small chip size and relatively large solder joints.

However, the micro-electronics market keeps demanding more powerful products with higher I/O counts and density, which has resulted in an continuous increase of chip size and decrease of the solder joint dimension. As a result, the solder joint reliability issue caused by the thermal mismatch between the silicon die and the packaging substrate has become a serious concern for future microelectronic devices and systems. Typically, an under-fill material is applied between the chip and the packaging substrate to strengthen the solder joint. However, with the continued decrease of the device pad pitch and stand-off height, the distribution of under-fill material at the chip-to-substrate gap will become increasingly challenging.

A number of compliant interconnect technologies have recently been suggested to address this challenge. The basic underlying idea is that, if the interconnect structures are flexible enough, the strain energy arising from thermal mismatch can be absorbed and then the under-fill material can be finally eliminated. As one example, the wide area vertical expansion (WAVE) technology integrates the silicon die with a stress decouple layer made of a low-modulus encapsulant and a copper intra-chip wiring layer made of two metal/polyimide substrates. The strain deformation of the solder joints due to thermal mismatch is minimized in the WAVE technology, since the stress decouple layer and flexible intra chip wiring link allow relative movement of the die and the PCB in the X, Y, and Z directions. However, the main disadvantages of the WAVE technology are the complicated manufacturing process and the proprietary materials involved.

Other compliant interconnection technologies involve micro- or nano-springs for mounting the solder ball or bump. However, currently such technologies are typically limited to some materials by exploiting their specific properties such as residual stresses for spring release, or so-called spring alloys for providing resilience to wire bonds.

In another compliant interconnect technology, Helix-type interconnects are formed utilizing repeated photolithography and copper electroplating processes. The whole interconnection structure is fabricated in a bottom-up sequence, and the out-of-plane freedom and flexibility are achieved by repetitive stacking of spring arms. The main issue related to this technology includes the complicated fabrication process and thus high cost associated with multi-layer polymer deposition, metallization and electroplating.

A need therefore exists to provide a compliant interconnect technology that addresses at least one of the abovementioned problems.

### SUMMARY OF THE INVENTION

In accordance with a first aspect of the present invention there is provided an interconnect structure for interconnecting an integrated circuit (IC) chip to a next level, the interconnect structure comprising one or more planar micro-spring elements formed on a packaging surface of the chip and connected to an interconnection pad; wherein the interconnection pad is resiliently moveable horizontally and vertically with respect to the surface of the chip.

The interconnect structure may further comprise a solder layer formed on the interconnection pad.

The interconnect structure may further comprise a metal column formed between the interconnection pad and the solder layer.

The column may extend substantially vertically with respect to the surface of the chip.

The interconnect structure may comprise an array of interconnection pads each of which is connected to one or more planar micro-spring elements formed on the surface of the chip.

Each spring element may comprise at least one in-plane bend for facilitating resilience of the planar micro-spring during movement of the interconnection pad.

The interconnect structure may further comprise a frame element interconnecting the spring elements, the frame element being mounted on the packaging surface of the chip and being further connected to a chip pad of the chip for electrical interconnection via an interconnection plug.

The spring elements may be electrically interconnected in parallel to reduce the electrical resistance of the interconnect structure.

The interconnection pad and spring elements may be suspended across a cavity on the packaging surface for facilitating movement of the interconnection pad relative to the chip surface.

In accordance with a second aspect of the present invention there is provided an method of interconnecting an integrated circuit (IC) chip to the next level, the method comprising forming one or more planar micro-spring elements on a packaging surface of the chip, the micro-spring elements connected to an interconnection pad; wherein the interconnection pad is resiliently moveable horizontally and vertically with respect to the surface of the chip.

In accordance with a third aspect of the present invention there is provided a method of fabricating an interconnect structure on an integrated circuit (IC) chip at wafer level, the method comprising forming one or more planar micro-spring elements on a packaging surface of the chip, the micro-spring elements connected to an interconnection pad, wherein the interconnection pad is resiliently moveable horizontally and vertically with respect to a surface of the chip.

The method may further comprise forming a solder layer on the interconnection pads.

The method may further comprise forming a metal column on the interconnection pad followed by forming a solder layer on the metal column.

The method may further comprise forming a frame element interconnecting the spring elements on the packaging surface of the chip.

The spring elements may be electrically interconnected in parallel to reduce the electrical resistance of the interconnect structure.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a scanning electron microscope image of a planar micro-spring interconnect according to an example embodiment.

FIG. 2 shows a scanning electron microscope image of an interconnect array according to an example embodiment.

FIG. 3 shows a flowchart illustrating a process flow of a planar micro-spring interconnect fabrication method according to example embodiments.

FIGS. 4a to f are schematic drawings of planar micro-spring structures according to example embodiments.

FIGS. 5a and b are graphs of the in-plane compliance and the out-of-plane compliance respectively of micro-spring structures according to example embodiments.

FIGS. 6a to c are graphs showing the electrical parasitics of micro-spring structures as a function of frequency, according to example embodiments.

FIGS. 7a to d are graphs showing the dependency of compliances of micro-spring structures according to example embodiments on selected design parameters.

FIG. 8 is a graph showing the influence of the sacrificial material on the transmission characteristics of planar micro-spring interconnects according to an example embodiment.

### DETAILED DESCRIPTION OF THE PREFERRED EMBODIMENTS

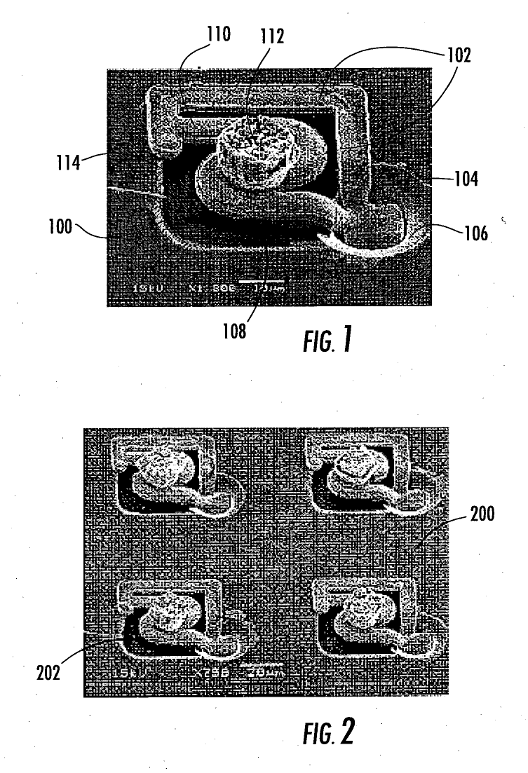

FIG. 1 shows a scanning electron microscope (SEM) image of a planar micro-spring interconnect 100 according to an example embodiment. The micro-spring interconnect 100 comprises a metal frame 102, and an interconnection plug 104, connected to a die pad (not shown) through a via 106.

The micro-spring 100 further comprises two J-shaped micro-spring elements 108, 110, and an interconnect pad (hidden) supporting a solder ball 112 for connection to a next-level.

The two J-shaped micro-spring elements 108, 110 and the interconnect pad (hidden) are released from the substrate 114, and therefore the micro-spring 100 is capable of providing the vertical compliance (Z direction) required for wafer-level test and burn-in. Additionally, it will be appreciated that the micro-spring 100 is flexible along the in-plane directions, which reduces strain occurring in the solder joint.

Due to the small dimensions in the example embodiment (compare scale of 10 μm as indicated in FIG. 1), the inductance and capacitance associated with the micro-spring 100 interconnect are small. Furthermore, the parallel electrical paths along the suspended spring elements 108 and 110 are shorted by the metal frame 102 so that the effective electrical resistance can remain at acceptably low levels. As a result, the power loss through the micro-spring 100 interconnect can be reduced to very low values.

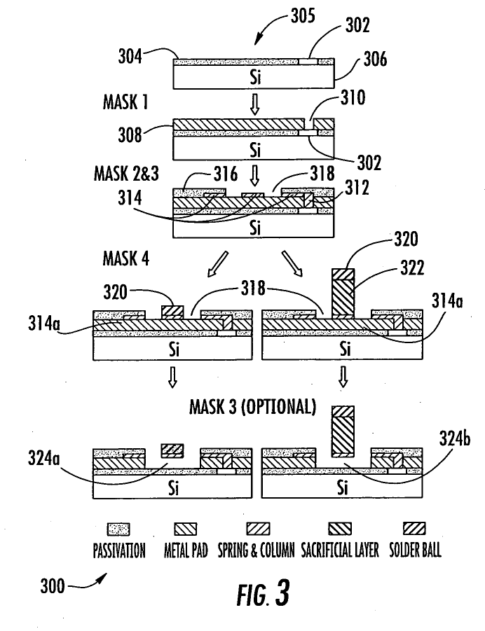

FIG. 2 shows an SEM image of an interconnect array 200 of micro-springs 202 with a pitch of 100 μm in this example embodiment. It will be appreciated by a person skilled in the art that with optimization of the manufacturing processes and dimensioning of the micro-springs, ultra-high-density interconnection arrays may be provided, for example to over 27,000 I/Os per cm².

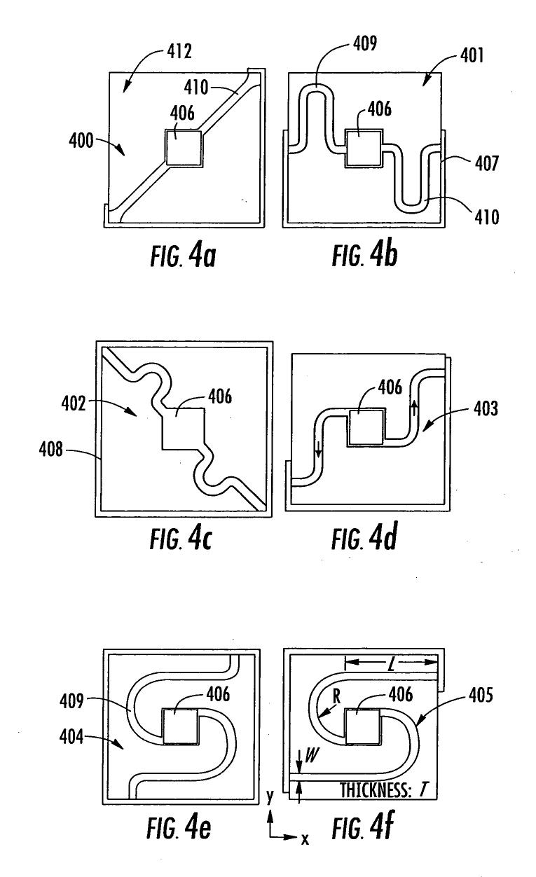

FIG. 3 shows a flowchart 300 illustrating the process flow of a wafer-level planar micro-spring interconnect fabrication process as part of a chip fabrication process, according to example embodiments. An exposed chip pad (Cu) 302 and a passivation layer (SiO₂) 304 form a packaging surface 305 of the chip, the chip pad 302 being one of many on a chip and the chip being one of many on a Si wafer 306, which includes device layer(s) (not shown) of the chip. A sacrificial layer 308 is deposited on the packaging surface 305 utilizing a first mask (not shown). Both organic and in-organic materials may be used as the sacrificial layer 308. In the example embodiment, the sacrificial layer 308 comprises an organic polymer in the form of benzocyclobutene (BCB), at a thickness of about 7.4 μm, deposited using a spin-on method.

The BCB spin-coated layer 308 is hard cured at about 250° C. for about one hour, and via patterns 310 are fabricated to expose the Cu pads 302. In the example embodiment, the via 310 size is about 15×15 μm², and a dry etch process in a 30% CF₄/70% O₂ plasma with a total pressure of about 50 mTorr is used.

Next, a 200 Å Ti/500 Å Au seed layer (not shown) is sputter-deposited, followed by a photoresist coating utilizing a second mask (not shown) for patterning, and bottom-up Cu electroplating. The plating process fills the vias as indicated at numeral 312 and also fills shallow trenches in the photo resist coating (not shown) to form the planar micro-springs as indicated at numeral 314.

The photoresist (not shown) and the exposed seed layer (not shown) are then stripped off. It is noted that many Au wet etchants attack Cu. In the example embodiment, N₂ sputtering etching was used to remove Au, with a low throughput. On the other hand, the thin Ti layer can be easily removed by either a wet etchant or a fluorine-based plasma. A 5 KÅ plasma enhanced chemical vapor deposition (PECVD) silicon oxide layer 316 is then deposited using a third mask (not shown) to form an etching window 318 for the later release process. The silicon oxide layer 316 also functions as a mechanical anchor to the peripheral metal frame of the micro-spring being manufactured.

Next, another 200 Å Ti/500 Å Au seed layer (not shown) is sputter deposited and a thick photoresist of about 15 μm (not shown) is patterned to expose the central interconnection pad 314a of the interconnect structure. Solder is then electroplated onto the central interconnection pad 314a. In a modified embodiment, a copper column 322 is electroplated onto the central interconnection pad 314a prior to the electroplating of the solder layer. Subsequently, the exposed seed layer (not shown) is removed, and the BCB layer 308 is isotropically etched through the pre-defined oxide window 318 to release the spring structures 324a and b. The third mask may again be used during the BCB layer 308 etching.

The fabrication of the additional Cu column 322 can enhance the compliances of the interconnect structure, as required. The Cu column 322 further facilitates the flip-chip assembly process because of the increased stand-off height between the Si chip and the next-level, e.g. a PCB substrate. Those advantages may be balanced with the “penalty” of an additional process step.

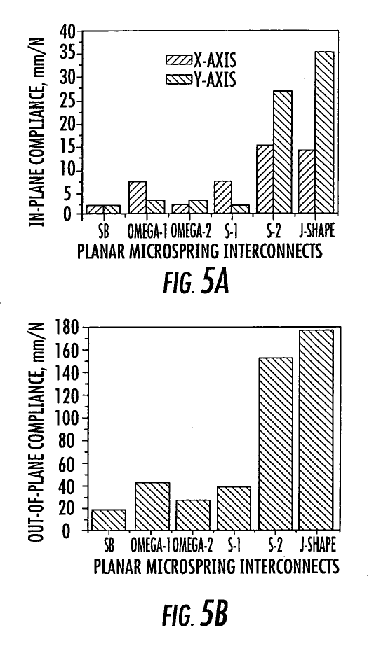

FIGS. 4a to f are schematic drawings of planar micro-spring structures according to different example embodiments. The different structures are referred to as: (a) simple beam (SB); (b) omega-1; (c) omega-2; (d) S-1; (e) S-2; and (f) J-shaped. In FIGS. 4a to f, the spring structures 400 to 405 are settled and suspended over a 40×40 μm² cavity area e.g. 412, and having a central interconnection pad 406 of about 10×10 μm², spring element widths of about 2 μm, and thicknesses of about 2 μm. The depth of the square cavity area e.g. 412 is substantially the same as the thickness of the sacrificial layer used during fabrication (compare FIG. 3). In the arrangements shown in FIGS. 4a to f, the spring structures e.g. 400 include two spring elements 409, 410 connected to the interconnection pad 406. For each shape, the spring elements 409, 410 are typically designed to achieve a maximum effective spring length within design rule limits of each shape, as will be described in more detail below. The outer ends of the spring elements 409, 410 are connected together by a metal frame 407 which extends partially around the perimeter of the square area, as illustrated in FIGS. 4a, 4b, 4d and 4f. In a modified embodiment, the frame can extend around the entire perimeter as shown in FIGS. 4c and 4e.

Table 1 shows the major material properties involved in mechanical and electrical simulations of the example embodiments. The mechanical simulation model consists of the spring structure and solder ball, while the high-frequency electrical simulation is conducted in a flip-chip package scenario. The scattering parameters obtained from the electrical simulation using the High Frequency Structure Simulator (HFSS) software were translated into parasitic values using transmission line theory.

TABLE 1
Material properties used for simulation

| | Cu | 63Sn37Pb | Si | FR4 |
|---|---|---|---|---|
| Elastic modulus, GPa | 127.4 | 33.6 | — | — |
| Poisson's ratio | 0.36 | 0.4 | — | — |
| Electrical | 5.88 × 10⁷ | 7 × 10⁶ | — | — |
| conductivity, S/m | | | | |
| Dielectric constant | — | — | 11.9 | 4.4 |
| Loss tangent | — | — | 0.005 | 0.02 |

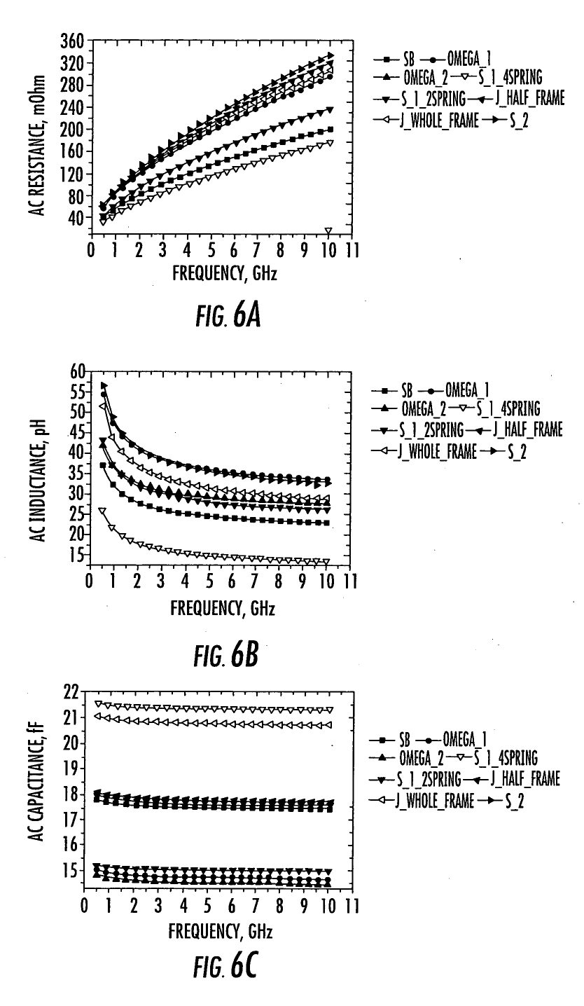

FIGS. 5a and b show the in-plane compliance and the out-of-plane compliance respectively of the different structures shown in FIGS. 4a to f. As can be seen from FIGS. 5a and b, the J-shaped spring structure has the highest compliances in both horizontal and vertical directions, which is consistent with its highest effective length. Since all of the structures shown in FIGS. 4a to f are not axis-symmetrical, note should be taken regarding the orientation layout with reference to the chip to achieve the required X- and Y-axis compliances for a particular interconnection.

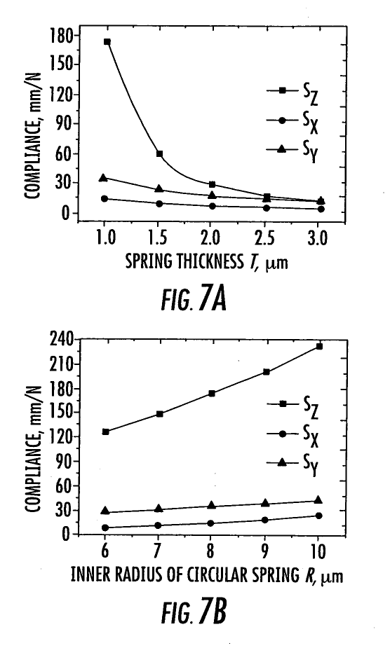

On the other hand, the electrical characteristics, particularly the electrical resistances have an opposite dependence upon the structure geometry, compared to the compliance characteristics. This is demonstrated in FIGS. 6a to c, which show the electrical parasitics of the various spring designs as a function of frequency, more particularly (a) resistance; (b) inductance, and (c) capacitance. As can be seen from FIGS. 6a, the J-shaped and S-2 designs show the maximum electrical resistance. The inductance is partially affected by the effective beam lengths, but the space between springs and between beams and metal frames also plays a roll since those spaces induce mutual inductance as a contribution to the total inductance as can be seen from FIG. 6b.

Further design considerations for the metal frame 102 (FIG. 1) and the spring elements in example embodiments will now be described. Either a partial metal frame (compare e.g. 407 in FIG. 4b) or a full metal frame (compare e.g. 408 in FIG. 4c) can be used to electrically connect the spring elements in parallel without influence on the mechanical compliances. However, as can be seen from FIG. 6c, for the J-shaped structure, a whole metal frame introduces 17% more capacitance but negligibly less resistance (see FIG. 6a), compared to the partial metal frame option. For some designs such as the arrangements shown in FIGS. 4a to d, four or more spring elements can be fabricated instead of two in different embodiments to reduce the electrical resistance and inductance at the expense of compliances and capacitance. As will be appreciated by a person skilled in the art, the planar spring structures in the example embodiments may be used with different trade-offs between mechanical and electrical performance. Also, a single spring element may be fabricated in another embodiment.

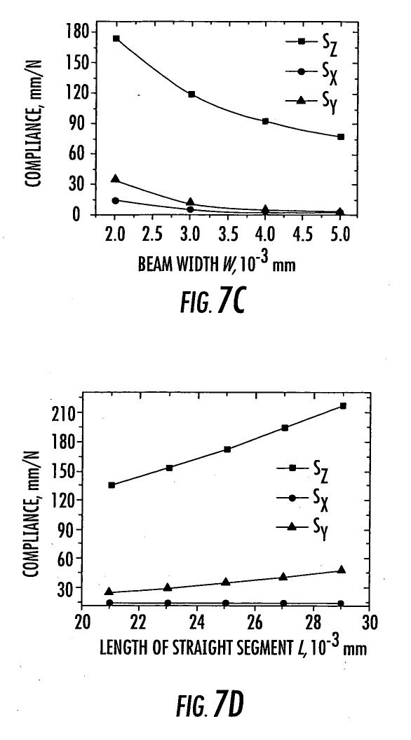

The three-dimensional compliances of the J-shaped interconnects (inclusive of the solder joint) were further studied as a function of the spring geometry parameters as indicated in FIG. 4f. FIG. 7a to d show the typical dependency of the compliances on these parameters, more particularly (a) the spring thickness T; (b) the inner radius R of the circular segment; (c) the spring width W; and (d) the length of the straight segment L. As can be seen from FIGS. 7a to d, the compliances decrease with increase of spring thickness and width, and this inverse correlation is most significant in the smaller dimension range. In contrast, the influence of the other two parameters R and L is lower.

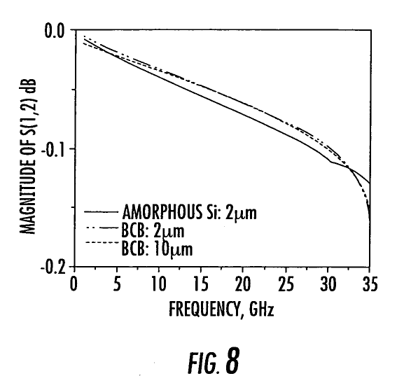

FIG. 8 shows the influence of the sacrificial material on the transmission characteristics of planar micro-spring interconnects according to example embodiments. As can be seen from FIG. 8, BCB as the sacrificial layer induces less signal loss than an amorphous Si sacrificial layer, due to the lower dielectric constant of BCB. An increase of BCB thickness from 2 μm to 10 μm did not bring about an evident improvement in the transmission performance in the example embodiment.

In comparison with existing techniques, the described embodiments provide a method to fabricate compliant interconnections with fewer complicated processes. The interconnection structure is realized on the wafer level with a batch process that can be easily integrated into the back-end-of-line (BEOL) integrated circuit process. Compared to Helix-type interconnects in which multi-layer polymer deposition and electroplating are required, the described embodiments provide a method to realize an interconnection with high compliances but significantly less demanding requirements for materials and process integration.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, it will be appreciated that the present invention is not limited to the manufacturing steps, sequences, and conditions as described for the example embodiments. Furthermore, it will be appreciated that the present invention is not limited to the specific materials referred to in the described embodiments. Also, the present invention is not limited to the micro-spring shapes of the described embodiments.

That which is claimed is:

1. An interconnect structure for interconnecting an integrated circuit (IC) chip to a next level, the interconnect structure comprising:
one or more planar micro-spring elements formed on a packaging surface of the chip and connected to an interconnection pad;
wherein the interconnection pad is resiliently moveable horizontally and vertically with respect to the surface of the chip.

2. The interconnect structure as claimed in claim 1, further comprising a solder layer formed on the interconnection pad.

3. The interconnect structure as claimed in claim 2, further comprising a metal column formed between the interconnection pad and the solder layer.

4. The interconnect structure as claimed in claim 3, wherein the column extends substantially vertically with respect to the surface of the chip.

5. The interconnect structure as claimed in claim 1, comprising an array of interconnection pads each of which is connected to one or more planar micro-spring elements formed on the packaging surface of the chip.

6. The interconnect structure as claimed in claim 1, wherein each spring element comprises at least one in-plane bend for facilitating resilience of the planar micro-spring during movement of the interconnection pad.

7. The interconnect structure as claimed in claim 1, further comprising a frame element interconnecting the spring elements, the frame element being mounted on the packaging surface of the chip and being further connected to a chip pad of the chip for electrical interconnection via an interconnection plug.

8. The interconnect structure as claimed in claim 7, wherein the spring elements are electrically interconnected in parallel to reduce the electrical resistance of the interconnect structure.

9. The interconnect structure as claimed in claim 1, wherein the interconnection pad and spring elements are suspended across a cavity on the packaging surface of the chip for facilitating movement of the interconnection pad relative to the chip surface.

10. A method of fabricating an interconnect structure on an integrated circuit (IC) chip at wafer level, the method comprising:
forming one or more planar micro-spring elements on a packaging surface of the chip, the micro-spring elements connected to an interconnection pad, wherein the interconnection pad is resiliently moveable horizontally and vertically with respect to the packaging surface of the chip.

11. The method as claimed in claim 10, further comprising forming a solder layer on the interconnection pads.

12. The method as claimed in claim 10, further comprising forming a metal column on the interconnection pad followed by forming a solder layer on the metal column.

13. The method as claimed in claim 10, wherein the method further comprises forming a frame element interconnecting the spring elements on the packaging surface of the chip.

14. The method as claimed in claim 13, wherein the spring elements are electrically interconnected in parallel to reduce the electrical resistance of the interconnect structure.

15. A method of interconnecting an integrated circuit (IC) chip to the next level, the method comprising:
forming one or more planar micro-spring elements on a packaging surface of the chip, the micro-spring elements connected to an interconnection pad;
wherein the interconnection pad is resiliently moveable horizontally and vertically with. respect to the surface of the chip.
